(19) United States
(12) Patent Application Publication
(10) Pub. No.: US 2026/0371594 A1
(43) Pub. Date: Nov. 19, 2026

(54) MEMORY DEVICES HAVING SOURCE SEGMENTATIONS AT MID-TRENCH LOCATIONS

(71) Applicant: Micron Technology, Inc., Boise, ID (US)

(72) Inventors: Nicolo' Gravellini, Milano (IT); Lorenzo Pedrazzetti, Soncino (IT); Paolo Tessariol, Arcore (IT)

(21) Appl. No.: 19/212,071

(22) Filed: May 19, 2025

(51) Int. Cl. H10B 43/35; H10B 41/10; H10B 41/35; H10B 43/10

(52) U.S. Cl. CPC H10B 43/35; H10B 41/10; H10B 41/35; H10B 43/10

(57) ABSTRACT

A variety of applications can include a memory device with source segmentations at mid-trench locations of a vertical plane-cell based architecture. A memory device can include a first set of strings of memory cells positioned on a trench and a second set of strings of memory cells positioned on the trench. The strings of the first and second sets can extend vertically from the trench. The second set can be separated from the first set at a mid-trench location of the trench. A first source plate can be coupled to the first set of strings. A second source plate can be coupled to the second set of strings. The second source plate can be separated from the first source plate at the mid-trench location separating the first set of strings from the second set of strings. The first and second source plates can be controllable independent of each other.

### FIELD OF THE DISCLOSURE

Embodiments of the disclosure relate generally to integrated circuits, and more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, components of a memory integrated circuit.

### BRIEF DESCRIPTION OF THE DRAWINGS

The drawings, which are not necessarily drawn to scale, illustrate generally, by way of example, but not by way of limitation, various embodiments discussed in the present document.

FIG. 1 represents a top view of component features of an arrangement of a trench for a vertical plate-cell based memory device architecture, in accordance with various embodiments.

FIG. 2 is a flow diagram of features of an example method of forming a memory device, in accordance with various embodiments.

FIG. 3 is a top view representation of a layout of a block of memory cells of an example memory array of a memory device, in accordance with various embodiments.

FIG. 4 is a top view representation of a layout of a block of memory cells of an example memory array of a memory device having rows of trenches and a source segmentation in which segmentation is different from being at every mid-trench location along the rows of trenches, in accordance with various embodiments.

FIG. 5 is a representation of a cross section of a trench of a row of trenches of an example memory array along an access line direction for the memory array, with respect to segmented source plates, in accordance with various embodiments.

FIG. 6 is a top view representation of a layout of an example memory array having multiple blocks of memory cells in a plane, in accordance with various embodiments.

FIG. 7 is an illustration of chunks of data allocated by source plate, in accordance with various embodiments.

FIG. 8 is a representation of an example components of a memory device, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

To increase data storage density of memory integrated circuits, architectures for memory arrays have been developed for 3D memory devices. These architectures include a number of different structural layouts. One architecture for a 3D NAND memory includes vertical pillars having material for memory cells with gate-all-around (GAA) transistors wrapped around the pillars with the GAA transistors distributed at different tiers along the vertical pillars. The vertical pillars are typically structured as cylindrical pillars with memory cells in a circular orientation around a respective vertical pillar. Another architecture for a 3D NAND memory is designed without a circular GAA memory cell geometry. In this other architecture, memory cells are constructed at a sidewall of a trench with a storage region against a vertical flat channel structure provided by vertical pillars having a rectangular cross-section, where storage regions are at opposite sidewalls of the trench. The vertical flat channel structure of the pillar, forming a string of memory cells, provides a conductive path to a source for operation of the memory cells as transistor structures. The different tiers of memory cells corresponds to access lines coupled to gates to the storage regions being separated by electrical insulating regions. This configuration resembles a planar configuration tilted on its side and can be referred to as a vertical planar (VP)-cell based architecture or a 3D trench cell architecture. The VP-cell based architecture can provide increased storage density over the architecture having GAA transistors about a cylindrical pillar. However, as array density increases across generations of memory ICs, meeting performance improvement targets can become more difficult. Such performance targets can include reading data at faster speeds.

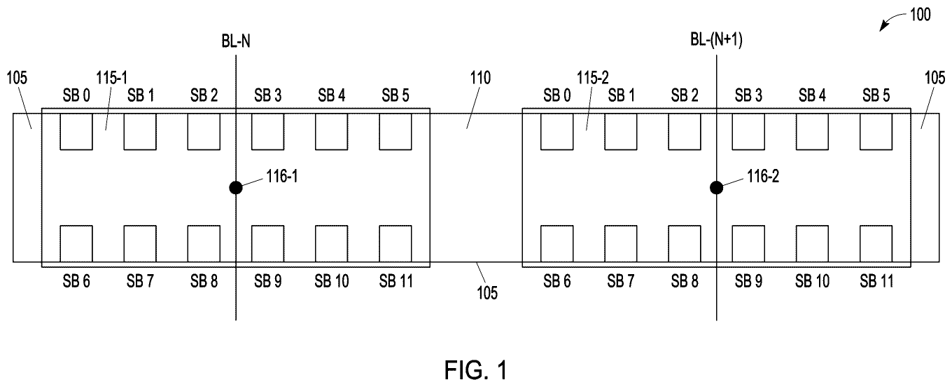

FIG. 1 represents a top view of component features of an arrangement 100 of a trench 105 for a VP-cell based memory device architecture. Trench 105 can include, disposed thereon, two sets of strings of memory cells of a memory array of a memory device. Trench 105 is one of many trenches that can make-up the memory array having memory cells coupled to data lines (BLs) and access lines (WLs). The memory device can be a NAND memory device. The first set of strings can include twelve sub-blocks of data SB 0, SB 1, . . . SB 10, and SB 11 arranged as strings, where each string is coupled to the same transistor 115-1. Transistor 115-1 is coupled to a N^{th} BL (BL-N) at BL node 116-1. The second set of strings can include twelve sub-blocks of data SB 0, SB 1, . . . SB 10, and SB 11 arranged as strings, where each string of the second set is coupled to the same transistor 115-2. Transistors 115-2 is coupled to a (N^{th}+1) BL (BL−(N+1)) at BL node 116-2. Transistors 115-1 and 115-2 can be thin film transistors (TFTs). For a memory array having multiple trenches with multiple strings of memory cells coupled to multiple BLs, each BL is associated with a single transistor coupled to the strings of one set of strings of a respective trench. Strings belonging to the same set or, equivalently, connected to the same transistor, belong to different sub-blocks. In the example of FIG. 1, there are twelve stings per set of trench 105, totaling twenty-four strings per trench organized in two common BL nodes 116-1 and 116-2, one BL node per set.

The two sets of strings in trench 105 are separated by a mid-trench location 110. With a memory array structured as rows of trenches, with each trench structured similar to trench 105, mid-trench location 110 can be structured as a sufficiently large region to be used as a space to start a lateral trim and etch process that creates a breaking in the string pattern in trench 105. In a conventional VP-cell based architecture, strings of all the trenches of a memory array can be coupled with an advanced interconnect approach with a continuous common source plate.

In various embodiments, a source for a memory array is segmented into a set of source plates that can provide a conduction path for memory cells. Each source plate of the set can be controlled independent of each other. Such independent control can include setting the source plates to different voltages. In an approach to forming the set of source plates, a continuous common source plate can be segmented at a mid-trench location of a trench, the part of the trench that separates the two strings sets of the trench. With the memory array structured as rows of trenches having two sets of strings extending vertically therefrom, the rows can be aligned such that mid-trench locations are along a line in a plane of the rows. In a VP process flow, a sufficiently wide opening in the middle of the trench is used to enable the lateral trim and etch process that creates the concavities for the cell and string formation, which opening unavoidably breaks the cell pattern in the middle of the trench. This “inefficiency” in the string pattern can be leveraged to segment the continuous common source plate into the set of source plates that can provide for multiple chunks of data to be read independently. Independently reading chunks of data can remove the capacitive load of unread chunks.

The source segmentation in a VP-cell based architecture, as taught herein, provides a mechanism to boost read performance, by making possible the reading of small chunks of data independently such that the capacitive load of the chunks of data, for which reading is not desired, is cut off by cutting off strings associated with these non-read chunks, via independently controlled source plates. Reading small chunks of data can enhance performance by providing a read operation at significantly greater speed. The source segmentation at the mid-trench locations splits each page into multiple small chunks that can be read fast, as the strings belonging to the other chunks can be cut off by tuning their source potential. The chunks can be, but are not limited to chunks of 1 kB, potentially as chunks of less than 1 kB. The granularity of the segmentation can be tuned to meet design specifications, for example, by one source cut every N trenches along the direction of a row.

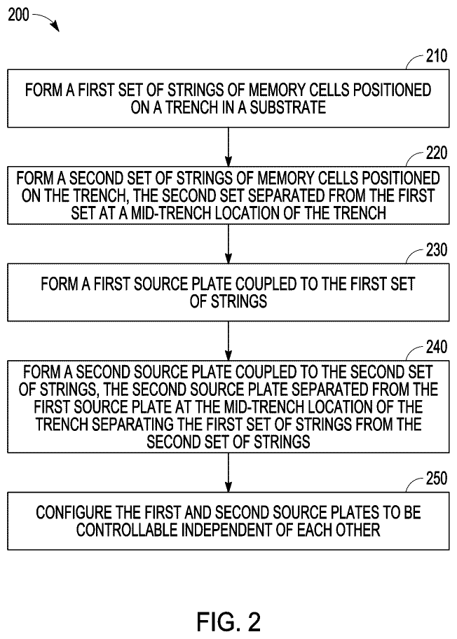

FIG. 2 is a flow diagram of features of an example embodiment of a method of forming a memory device. At 210, a first set of strings of memory cells is formed positioned on a trench in a substrate. The strings of the first set extend vertically from the trench. At 220, a second set of strings of memory cells is formed positioned on the trench, where the strings of the second set extend vertically from the trench. The second set is separated from the first set at a mid-trench location of the trench. At 230, a first source plate is formed coupled to the first set of strings such that the strings of the first set extend vertically from the first source plate. At 240, a second source plate is formed coupled to the second set of strings such that the strings of the second set extend vertically from the second source plate. The second source plate is separated from the first source plate at the mid-trench location of the trench separating the first set of strings from the second set of strings. At 250, the first and second source plates are configurable to be controllable independent of each other. The first and second source plates can be coupled to a controller that can selectively apply voltages to the first and source plates such that when strings of one set of strings of the trench are active, the string of the other set of strings of the trench are in an off status.

Variations of method 200 or methods similar to method 200 can include a number of different embodiments that may be combined depending on the application of such methods or the architecture or operational flow for which such methods are implemented. Such methods can include forming the first source plate and the second source plate by forming a source region coupled to the strings of the first set of strings and coupled to the strings of the second set of strings and cutting the source region at the mid-trench location of the trench that separates the first set of strings from the second set of strings. In an approach to cutting the source region into a set of source plates, the source region and the strings can be oriented such that the strings are in a negative vertical direction with region to the source region.

Variations of method 200 or methods similar to method 200 can include forming the trench as one of multiple trenches arranged as a row of trenches having two sets of strings separated at mid-trench locations, and performing one source segmentation every N mid-trench locations, N being a positive integer. Spaces can be generated at the mid-trench locations to perform lateral trim and etch processes, creating breaks in a string pattern in the trenches of the row of trenches. Performing the one source segmentation every N mid-trench locations can be conducted by etching a continuous source region in a backside source process flow. Variations can include selecting the value of N to fit a performance specification for the memory device and to meet design constraints for the memory device.

In various embodiment, a memory device can include a first set of strings of memory cells positioned on a trench in a substrate, where the strings of the first set extend vertically from the trench. A second set of strings of memory cells can be positioned on the trench, where the strings of the second set extends vertically from the trench and the second set is separated from the first set at a mid-trench location of the trench. A first source plate can be coupled to the first set of strings, where the strings of the first set extend vertically from and operate with the first source plate. A second source plate can be coupled to the second set of strings, where the strings of the second set extend vertically from and operate with the second source plate. The second source plate can be separated from the first source plate at the mid-trench location separating the first set of strings from the second set of strings. The first and second source plates can be controllable independent of each other.

Variations of such a memory device and its features can include a number of different embodiments and features that may be combined depending on the application of such memory devices, the format of such memory devices, and/or the architecture in which such memory devices are implemented. Features of such memory devices can include the strings of the first set being coupled to a transistor for the strings of the first set and the strings of the second set being coupled to another transistor for the strings of the second set. The transistor and the other transistor can be thin film transistors. The transistor can be associated with a single data line and the other transistor can be associated with another single data line. The strings of the first set of strings can be equal in number to the strings of the second set of strings.

Variations of such a memory device and its features can include the memory device having additional trenches in a row with the trench, where each given trench of the additional trenches has two sets of strings of memory cells positioned thereon. The two sets can be separated from each other along the given trench at a mid-trench location of the given trench. Variations of such a memory device can include strings of one set of the two sets of strings of an additional trench, directly adjacent the trench along the row, being coupled to and extending vertically from the second source plate. Strings of another set of the two sets of strings of the additional trench, directly adjacent the trench along the row, can be coupled to and extend vertically from a third source plate. The third source plate can be controllable independent of the first and second source plates. Variations of such an memory device can include the first source plate or the second source plate being coupled to the strings of the two sets of strings of one or more trenches of the additional trenches.

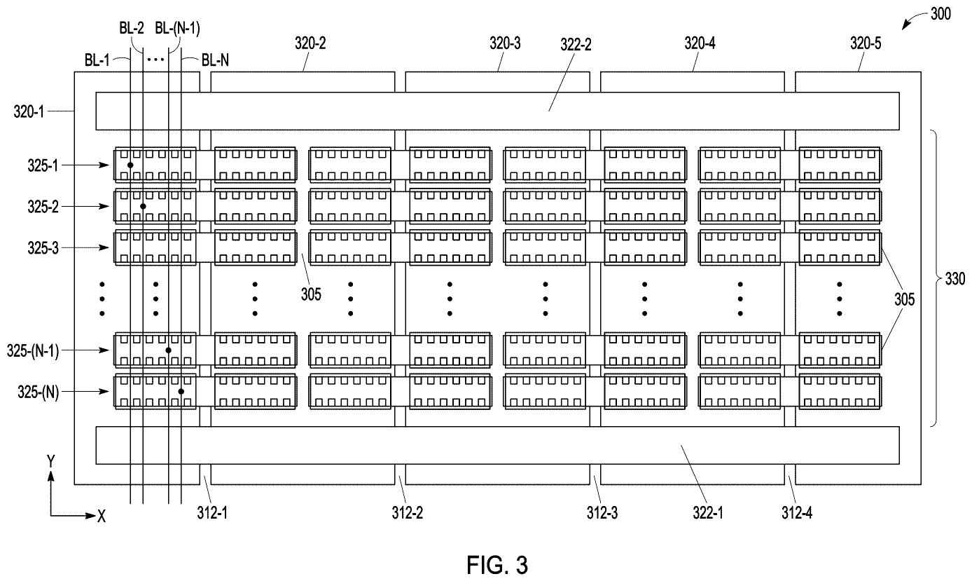

FIG. 3 is a top view representation of a layout of a block 330 of memory cells of an embodiment of a memory array 300 of a memory device. Block 330 can include rows 325-1, 325-2, 325-3 . . . 325-(N−1), 325-N of trenches 305, bounded by dielectric region 322-1 and dielectric region 322-2. Rows 325-1, 325-2, 325-3 . . . 325-(N−1), 325-N can be structured in a pattern along an x-direction. Though each row of block 330 is shown having four trenches, a block similar to block 330 can have more than four trenches. For ease of presentation, only a few trenches are labeled in FIG. 3. Each trench 305 can be realized with a similar structure that is similar to the structure of trench 105 of FIG. 1. Each trench 305 can include two sets of strings of memory cells with the two sets separated from each other at a mid-trench location of each trench 305, where the strings extend vertically (along a z-direction) from their respective trench 305. The strings of the two sets corresponding to a single trench 305 can be coupled to a single transistor to couple to a BL at a BL node. Each single transistor can be a TFT. Each single transistor of the trenches of rows 325-1 . . . 325-N of Block 330 can be associated with one BL. With rows 325-1, 325-2, 325-3 . . . 325-(N−1), 325-N running in the x-direction and strings running in the z-direction, BLs can run along the y-direction. For ease of presentation, only BL-1, BL-2 . . . BL-(N−1), and BL-N are shown in FIG. 3, though each trench 305 has an associated transistor coupled to an associated BL.

The strings of block 330 can be coupled to a set of source plates 320-1, 320-2, 320-3, 320-4, and 320-5. Source plate 320-1 can be separated from source plate 320-2 by a source segmentation 312-1. Source plate 320-2 can be separated from source plate 320-3 by a source segmentation 312-2. Source plate 320-3 can be separated from source plate 320-4 by a source segmentation 312-3. Source plate 320-4 can be separated from source plate 320-5 by a source segmentation 312-4. Source plates 320-1, 320-2, 320-3, 320-4, and 320-5 can be controlled independently from each other. For example, source plates 320-1, 320-2, 320-3, 320-4, and 320-5 can be selectively set at different voltages from each other. Selective application of voltages to the source plates can include setting selected ones of the source plates to a first voltage and setting selected other ones of the source plates to a second voltage different from the first voltage. With rows 325-1, 325-2, 325-3 . . . 325-(N−1), 325-N aligned with respect to each other, source segmentations can be structured to occur at the mid-locations of each trench in the y direction perpendicular to rows 325-1, 325-2, 325-3 . . . 325-(N−1), 325-N, which run in the x-direction.

Though trenches 305 are shown similar to trench 105 of FIG. 1, trench 305 can have features that vary from trench 105. For example, each given trench 305 can have more or fewer than twelve strings in set of the two sets, depending on the architecture of the 3D memory device in which the trench memory structures are formed. In another example, a given trench 305 can have more than two sets of strings, depending on the respective architecture for the 3D trench memory device. The location of the source segmentations can vary. Source segmentations can be tuned to meet design specifications by having one source segmentation for every N trenches along the direction of a row. In the example embodiment of block 330, N equals one. In another scenario, N can be selected to be greater than one. In another scenario, N can vary along the row direction. With N=1, except for the end source plates 320-1 and 320-5, each source plate 320-2, 320-3, and 320-4 can be coupled to one set of strings from each of two directly adjacent trenches 305. Segmenting a set of source plates or formation of trenches with sets of strings of memory cells can allow flexibility to the manner in which memory cells of strings are addressed for a memory operation.

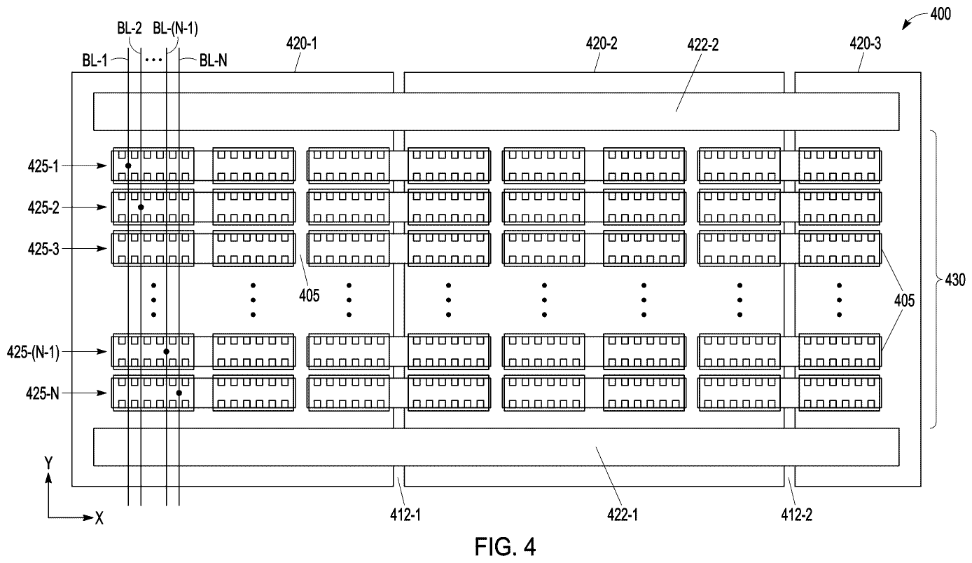

FIG. 4 is a top view representation of a layout of a block 430 of memory cells of an embodiment of an example memory array 400 of a memory device having rows of trenches and a source segmentation in which segmentation is different from being at every mid-trench location along the rows of trenches. Block 430 can include rows 425-1, 425-2, 425-3 . . . 425-(N−1), 425-N of trenches 405, bounded by dielectric region 422-1 and dielectric region 422-2. Rows 425-1, 425-2, 425-3 . . . 425-(N−1), 425-N can be structured in a pattern along an x-direction. Though each row of block 430 is shown having four trenches, a block similar to block 430 can have more than four trenches. For ease of presentation, only a few trenches are labeled in FIG. 4. Each trench 405 can be realized with a similar structure that is similar to the structure of trench 105 of FIG. 1 or trench 305 of FIG. 3. Each trench 405 can include two sets of strings of memory cells with the two sets separated from each other at a mid-trench location of each trench 405, where the strings extend vertically (along a z-direction) from their respective trench 405. The strings of the two sets corresponding to a single trench 405 can be coupled to a single transistor to couple to a BL at a BL node. Each single transistor can be a TFT. Each single transistor of the trenches of rows 425-1 . . . 425-N of Block 430 can be associated with one BL. With rows 425-1, 425-2, 425-3 . . . 425-(N−1), 425-N running in the x-direction and strings running in the z-direction, BLs can run along the y-direction. For ease of presentation, only BL-1, BL-2, BL-(N−1), and BL-N are shown in FIG. 4, though each trench 405 has an associated transistor coupled to an associated BL.

The strings of block 430 can be coupled to a set of source plates 420-1, 420-2, and 420-3. Source plate 420-1 can be separated from source plate 420-2 by a source segmentation 412-1. Source plate 420-2 can be separated from source plate 420-3 by a source segmentation 412-2. Source plates 420-1, 420-2, and 420-3 can be controlled independently from each other. For example, source plates 420-1, 420-2, and 420-3 can be selectively set at different voltages from each other. Selective application of voltages to the source plates can include setting selected ones of the source plates to a first voltage and setting selected other ones of the source plates to a second voltage different from the first voltage. With rows 425-1, 425-2, 425-3 . . . 425-(N−1), 425-N aligned with respect to each other, source segmentations can be structured to occur at the mid-locations of selected trenches in the y direction perpendicular to rows 425-1, 425-2, 425-3 . . . 425-(N−1), 425-N, which run in the x-direction. Source segmentations in memory array 400 has been tuned by having one source segmentation for every N trenches along the direction of a row, where N=2.

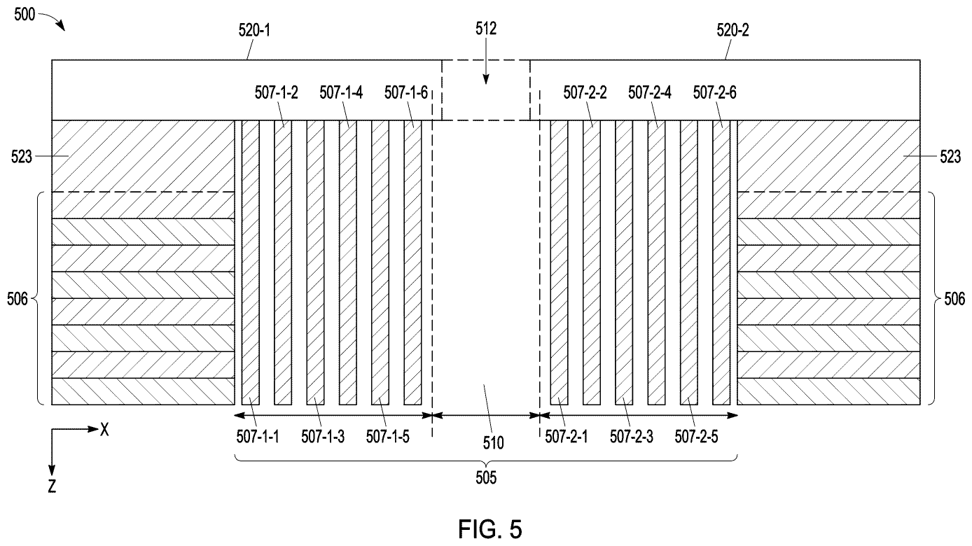

FIG. 5 is a representation of a cross section of a trench 505 of a row of trenches of an embodiment of an example memory array 500 along an access line direction for the memory array, with respect to segmented source plates 520-1 and 520-2. The representation of FIG. 5 reflects a fabrication of a set of source plates in a backside source process flow in which an array wafer and a control circuitry wafer are wafer bonded face to back. A continuous source plate can be formed and arranged on top of the bonded wafers such that the continuous source plate can be etched to obtain multiple source strips that extend over the top plane and along a y-direction with a x-direction along the access line direction and a z-direction extending vertically from the continuous source plate.

Trench 505 is a cavity that extends through a stack 506 of alternating regions of oxide and metal (OMOM) and a capping dielectric 523. Capping dielectric can be a capping oxide. Trench 505 can have two sets of strings of memory cells that extends through the stack. A first set of strings of the two sets of strings of trench 505 can include strings 507-1-1, 507-1-2, 507-1-3, 507-1-4, 507-1-5, and 507-1-6. A second set of strings of the two sets of strings of trench 505 can include strings 507-2-1, 507-2-2, 507-2-3, 507-2-4, 507-2-5, and 507-2-6. The two sets are separated by mid-trench location 510 that is a region in the middle of trench 505 used for the lateral trim and etch processes. In a backside source process flow, segmenting a continuous source plate into a set of source plates separated from each other can be performed by etching the continuous plate at a source segmentation location 512 directly above the mid-trench location 510 forming source plate 520-1 and source plate 520-2.

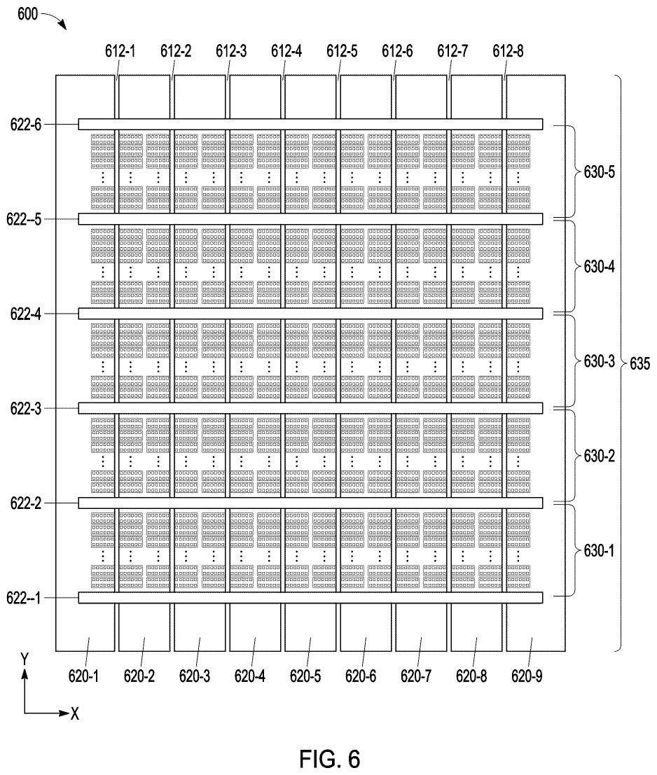

FIG. 6 is a top view representation of a layout of an embodiment of an example memory array 600 having multiple blocks in a plane 635. Memory array 600 can have blocks 630-1, 630-2, 630-3, 630-4, and 630-5. Each block 630-j is bounded by of a dielectric region 622-j and a dielectric region 622-(j+1), with j=1 . . . 5. Though five blocks are shown in FIG. 6, memory array 600 can have more or fewer than five blocks. Each block of blocks 630-1, 630-2, 630-3, 630-4, and 630-5 can be realized with a similar structure that is similar to the structure of block 320 of FIG. 3 with additional trenches for each row of trenches. Alternatively, each block of blocks 630-1, 630-2, 630-3, 630-4, and 630-5 can be realized with a similar structure that is similar to the structure of block 420 of FIG. 4 with additional trenches for each row of trenches, or other arrangement of rows of trenches.

For ease of presentation, rows of trenches and the trenches of the rows are not labeled in FIG. 6. Each trench can be realized with a similar structure that is similar to the structure of trench 105 of FIG. 1. Each trench can include two sets of strings of memory cells with the two sets separated from each other at a mid-trench location of each trench, where strings of memory cells extend vertically (along a z-direction) from their respective trench. The strings of the two sets corresponding to a single trench can be coupled to a single transistor to couple to a BL at a BL node. Each single transistor can be a TFT. Each single transistor of the trenches of the rows of trenches of each of blocks 630-1, 630-2, 630-3, 630-4, and 630-5 can be associated with one BL. With the rows running in the x-direction and strings running in the z-direction, BLs can run along the y-direction. For ease of presentation, the BLs are not shown in FIG. 6.

Strings of block 630-j, j=1 . . . 5, can be coupled to a set of source plates 620-k, k=1 . . . 9. Source plate 620-k can be separated source plate 620-(k+1) by a source segmentation 612-k, i=1 . . . 8, such that, for all k, source strips are formed in a y-direction. Source plates 620-1, 620-2, 620-3, 620-4, 620-5,620-6, 620-7, 620-8, and 620-9 can be controlled independently from each other. For example, source plates 620-k, k=1 . . . 9 can be selectively set at different voltages from each other. Selective application of voltages to the source plates can include setting selected ones of the source plates to a first voltage and setting selected other ones of the source plates to a second voltage different from the first voltage. Other permutation of voltage to source applications can be made. With rows of one block aligned with respect to each other with the rows of different blocks aligned with respect to each other, source segmentations can be structured to occur at the mid-locations of each trench in the y direction perpendicular to the rows, which run in the x-direction. Variations in the segmentation can be made depending on the relationship of segmentations to mid-trench locations for a given architectural design. The number of source segmentations can be tuned to fit performance requirements and to respect design constraints. For example, the granularity of the segmentation can be tuned to meet design specifications by one source cut every N trenches along the direction of the rows of blocks 630-j, j=1 . . . 5. The configuration of one source segmentation every mid-trench location, N=1, is an example of an upper limit case of segmentation. More optimized configurations can be achieved depending on the memory device designed. In an example architecture, sixteen source strips can be constructed with a page divided into sixteen chunks by 1 kB each.

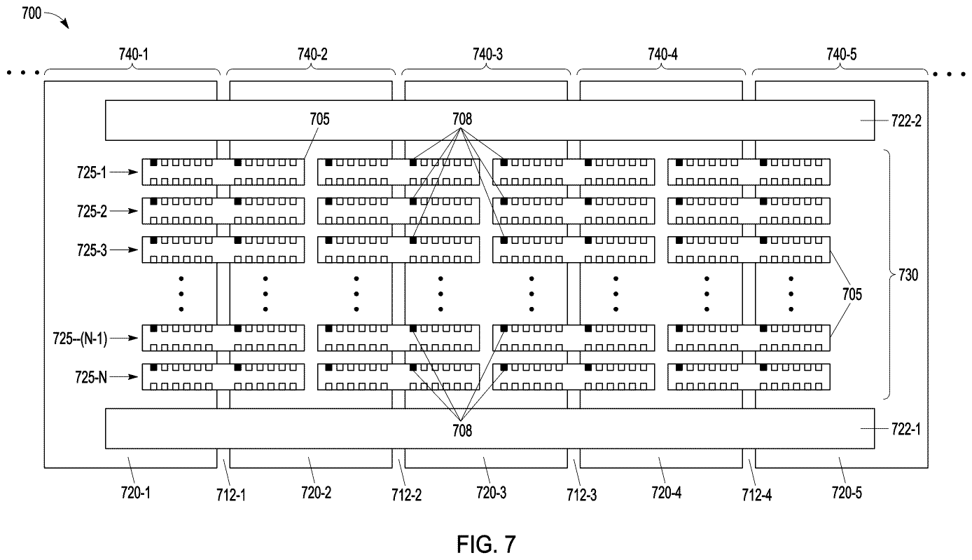

FIG. 7 is a top view representation of a layout of a block 730 of a memory array, representing splitting of pages into smaller chunks that will allow for fast read operations. Block 730 can be realized similar to block 330 of FIG. 3. Block 730 can include rows 725-1, 725-2, 725-3 . . . 725-(N−1), 725-N of trenches 705, bounded by dielectric region 722-1 and dielectric region 722-2. Rows 725-1, 725-2, 725-3 . . . 725-(N−1), 725-N can be structured in a pattern along an x-direction. Though each row of block 730 is shown having four trenches, a block similar to block 730 can have more than four trenches. For ease of presentation, only a few trenches are labeled in FIG. 7. Each trench 705 can be realized with a similar structure that is similar to the structure of trench 105 of FIG. 1 or the structure of trench 305 of FIG. 3. Each trench 705 can include two sets of strings of memory cells with the two sets separated from each other at a mid-trench location of each trench 705, where the strings extend vertically (along a z-direction) from their respective trench 705. The strings of the two sets corresponding to a single trench 705 can be coupled to a single transistor to couple to a BL at a BL node. Each single transistor can be a TFT. Each single transistor of the trenches of rows 725-1 . . . 725-N of Block 730 can be associated with one BL. With rows 725-1, 725-2, 725-3 . . . 725-(N−1), 725-N running in the x-direction and strings running in the z-direction, BLs can run along the y-direction. For ease of presentation, BLs are not shown in FIG. 7.

The strings of block 730 can be coupled to a set of source plates 720-1, 720-2, 720-3, 720-4, and 720-5. Source plate 720-k can be separated from source plate 320-(k+1) by a source segmentation 312-k, k=1 . . . 4. Source plates 720-1, 720-2, 720-3, 720-4, and 720-5 can be controlled independently from each other. For example, source plates 720-1, 720-2, 720-3, 720-4, and 720-5 can be selectively set at different voltages from each other. Selective application of voltages to the source plates can include setting selected ones of the source plates to a first voltage and setting selected other ones of the source plates to a second voltage different from the first voltage. With rows 725-1, 725-2, 725-3 . . . 725-(N−1), 725-N aligned with respect to each other, source segmentations can be structured to occur at the mid-locations of each trench in a direction perpendicular to rows 725-1, 725-2, 725-3 . . . 725-(N−1), 725-N.

Though trenches 705 are shown similar to trench 305 of FIG. 3, trench 705 can have features that vary from trench 305. For example, each given trench 705 can have more or fewer than twelve strings in set of the two sets, depending on the architecture of the 3D memory device in which the trench memory structures are formed. In another example, a given trench 705 can have more than two sets of strings, depending on the respective architecture for the 3D trench memory device. The location of the source segmentations can vary. Source segmentations can be tuned to meet design specifications by having one source segmentation for every N trenches along the direction of a row. In the example embodiment of block 730, N equals one. In another scenario, N can be selected to be greater than one. In another scenario, N can vary along the row direction. With N=1, except for the end source plates 720-1 and 720-5, each source plate 720-2, 720-3, and 720-4 can be coupled to one set of strings from each of two directly adjacent trenches 705. Segmenting a set of source plates can allow flexibility to the manner in which memory cells of strings are addressed for a memory operation.

FIG. 7 is an illustration of an embodiment of example chunks of data allocated by source plate. Block 730 has memory locations for chunks 740-1 . . . 740-5 for each source plate 720-1 . . . 720-5, respectively. For each chunk of data corresponding to source plate 720-3, memory cells that belong to the same page 708 can include a string (sub-block) of memory cells taken from the same corresponding location of each set of a trench over all rows 725-1 . . . 725-N of block 730. In reading data of chunk 740-3, source plate 720-3 is at a voltage such that the transistor structures of the associated memory cells and the transistors coupling the associated strings of trenches to BLs are in an on-status. For the read operation of chunk 740-3, the transistors for the strings corresponding to chunks 740-1, 740-2, 740-4, and 740-5 that are not be read can be placed in an off-status by placing a voltage on source plates 720-1, 720-2, 720-4, and 720-5 cutting off these transistors. With the strings of chunks 740-1, 740-2, 740-4, and 740-5 in an off-state, these strings do not contribute to the WL to ground capacitive load. The source segmentation at the mid-trench locations splits each page into multiple small chunks (potentially into chunks less than 1 kB) that can be read fast, as the strings belonging to the other chunks can be cut off, by tuning their respective source potentials.

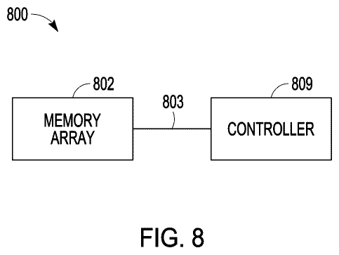

FIG. 8 is a representation of an embodiment of example components of a memory device 800. Memory device 800 can include a memory array 802 coupled to a controller 809 via conductive lines or circuitry 803. Memory array 802 can include rows of trenches in a substrate, where each trench has two sets of strings of memory cells positioned thereon. A first set of the two sets can be separated from a second set of the two sets along the trench at a mid-trench location of the trench. The strings of each of the two sets can extend vertically from the trench. A source for the strings of memory array 802 can be segmented into a set of source plates, where each source plate can be controllable independent of other source plates of the set of source plates. The sets of source plates can be structured with one source segmentation every N mid-trench locations of a row, N being a positive integer. Each source plate of the set of source plates can be coupled to strings of trenches defining segmentation boundaries of the source plate. Controller 809 can be structured to control the set of source plates to place one or more sets of strings in an off status in a read operation of the memory device. In various example architectures, N can equal one.

Variations of memory device 800 and its features can include a number of different embodiments and features that may be combined depending on the application of memory device 800, the format of such memory device 800, and/or the architecture in which memory device 800 is implemented. Features of memory device 800 can include the source segmented into sixteen source plates, dividing a page of data into sixteen chunks, with each chunk having data locations for one kilobyte. Variations can include memory cells that belong to a common chunk of a page being distributed among the rows of trenches having strings of memory cells coupled to one source plate of the set of source plates. Variations of memory device 800 can include controller 809 being arranged to read a chunk of a page of data from memory cells of strings distributed among the rows of trenches having strings of memory cells coupled to one source plate of the set of source plates, while holding, in an off-status, one or more chunks of the page distributed among the rows of trenches having strings of memory cells coupled to one or more source plates different from the one source plate. Variations of memory device 800 can include the rows of trenches arranged as blocks of memory cells, where each block is adjacent another block of the blocks of memory cells in a horizontal plane, with respect to the strings of each of the two sets of the trenches extending vertically from the trench.

The following are example embodiments of devices and methods, in accordance with the teachings herein.

An example memory device 1 can comprise a first set of strings of memory cells positioned on a trench in a substrate, the strings of the first set extending vertically from the trench; a second set of strings of memory cells positioned on the trench, the strings of the second set extending vertically from the trench, the second set separated from the first set at a mid-trench location of the trench; a first source plate coupled to the first set of strings, the strings of the first set extending vertically from the first source plate; and a second source plate coupled to the second set of strings, the strings of the second set extending vertically from the second source plate, the second source plate separated from the first source plate at the mid-trench location separating the first set of strings from the second set of strings, the first and second source plates controllable independent of each other.

An example memory device 2 can include features of example memory device 1 and can include the strings of the first set being coupled to a transistor for the strings of the first set and the strings of the second set being coupled to another transistor for the strings of the second set.

An example memory device 3 can include features of example memory device 2 and any of the preceding example memory devices and can include the transistor and the other transistor being thin film transistors.

An example memory device 4 can include features of example memory device 2 and any of the preceding example memory devices and can include the transistor being associated with a single data line and the other transistor being associated with another single data line.

An example memory device 5 can include features of any of the preceding example memory devices and can include the strings of the first set of strings being equal in number to the strings of the second set of strings.

An example memory device 6 can include features of any of the preceding example memory devices and can include additional trenches in a row with the trench, each given trench of the additional trenches having two sets of strings of memory cells positioned thereon, the two sets separated from each other along the given trench at a mid-trench location of the given trench.

An example memory device 7 can include features of example memory device 6 and any of the preceding example memory devices and can include strings of one set of the two sets of strings of an additional trench, directly adjacent the trench along the row, being coupled to and extend vertically from the second source plate; and strings of another set of the two sets of strings of the additional trench, directly adjacent the trench along the row, being coupled to and extend vertically from a third source plate, the third source plate controllable independent of the first and second source plates.

An example memory device 8 can include features of example memory device 6 and any of the preceding example memory devices and can include the first source plate or the second source plate being coupled to the strings of the two sets of strings of one or more trenches of the additional trenches.

In an example memory device 9, any of the memory devices of example memory devices 1 to 8 may be incorporated into an electronic apparatus further comprising a host processor or memory controller and a communication bus extending between the host processor/memory controller and the memory device.

In an example memory device 10, any of the memory devices of example memory devices 1 to 10 may be modified to include any structure presented in another of example memory device 1 to 10.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be formed or operated in accordance with any of the below example methods 1 to 10.

An example memory device 13 can comprise rows of trenches in a substrate, each trench having two sets of strings of memory cells positioned thereon, a first set of the two sets separated from a second set of the two sets along the trench at a mid-trench location of the trench, the strings of each of the two sets extending vertically from the trench; a source segmented into a set of source plates, each source plate controllable independent of other source plates of the set of source plates, with one source segmentation every N mid-trench locations of a row, N being a positive integer, each source plate of the set of source plates coupled to strings of trenches defining segmentation boundaries of the source plate; and a controller to control the set of source plates to place one or more sets of strings in an off status in a read operation of the memory device.

An example memory device 14 can include features of example memory device 13 and can include N being equal to one.

An example memory device 15 can include features of any of the preceding example memory devices 13 to 14 and can include the source being segmented into sixteen source plates, dividing a page of data into sixteen chunks, each chunk having data locations for one kilobyte.

An example memory device 16 can include features of any of the preceding example memory devices 13 to 15 and can include memory cells that belong to a common chunk of a page being distributed among the rows of trenches having strings of memory cells coupled to one source plate of the set of source plates.

An example memory device 17 can include features of any of the preceding example memory devices 13 to 16 and can include the controller being arranged to read a chunk of a page of data from memory cells of strings distributed among the rows of trenches having strings of memory cells coupled to one source plate of the set of source plates, while holding, in an off-status, one or more chunks of the page distributed among the rows of trenches having strings of memory cells coupled to one or more source plates different from the one source plate.

An example memory device 18 can include features of any of the preceding example memory devices 13 to 17 and can include the rows of trenches being arranged as blocks of memory cells, each block adjacent another block of the blocks of memory cells in a horizontal plane with respect to the strings of each of the two sets of the trenches extending vertically from the trench.

In an example memory device 19, any of the memory devices of example memory devices 13 to 18 may be incorporated into an electronic apparatus further comprising a host processor or memory controller and a communication bus extending between the host processor/memory controller and the memory device.

In an example memory device 20, any of the memory devices of example memory devices 13 to 19 may be modified to include any structure presented in another of example memory device 13 to 19.

In an example memory device 21, any apparatus associated with the memory devices of example memory devices 13 to 20 may further include a machine-readable storage device configured to store instructions as a physical state, wherein the instructions may be used to perform one or more operations of the apparatus.

In an example memory device 22, any of the memory devices of example memory devices 13 to 21 may be formed or operated in accordance with any of the below example methods 1 to 10.

An example method 1 of forming a memory device can comprise forming a first set of strings of memory cells positioned on a trench in a substrate, with the strings of the first set extending vertically from the trench; forming a second set of strings of memory cells positioned on the trench, with the strings of the second set extending vertically from the trench, the second set separated from the first set at a mid-trench location of the trench; forming a first source plate coupled to the first set of strings such that the strings of the first set extend vertically from the first source plate; forming a second source plate coupled to the second set of strings such that the strings of the second set extend vertically from the second source plate, the second source plate separated from the first source plate at the mid-trench location of the trench separating the first set of strings from the second set of strings; and configuring the first and second source plates to be controllable independent of each other.

An example method 2 of forming a memory device can include features of example method 1 of forming a memory device and can include forming the first source plate and the second source plate includes: forming a source region coupled to the strings of the first set of strings and coupled to the strings of the second set of strings; and cutting the source region at the mid-trench location of the trench separating the first set of strings from the second set of strings.

An example method 3 of forming a memory device can include features of any of the preceding example methods of forming a memory device and can include, with the trench being one of multiple trenches arranged as a row of trenches having two sets of strings separated at mid-trench locations, performing one source segmentation every N mid-trench locations, N being a positive integer.

An example method 4 of forming a memory device can include features of example method 3 of forming a memory device and any of the preceding example methods of forming a memory device and can include forming spaces at the mid-trench locations to perform lateral trim and etch processes, creating breaks in a string pattern in the trenches of the row of trenches.

An example method 5 of forming a memory device can include features of example method 3 of forming a memory device and any of the preceding example methods of forming a memory device and can include performing the one source segmentation every N mid-trench locations by etching a continuous source region in a backside source process flow.

An example method 6 of forming a memory device can include features of example method 3 of forming a memory device and any of the preceding example methods of forming a memory device and can include selecting N to fit a performance specification and to meet design constraints for the memory device.

In an example method 7 of forming a memory device, any of the example methods 1 to 6 of forming a memory device may be performed in forming a memory device further comprising forming a host processor and a communication bus extending between the host processor and a memory device.

In an example method 8 of forming a memory device, any of the example methods 1 to 7 of forming a memory device may be modified to include operations set forth in any other of example methods 1 to 7 of forming a memory device.

In an example method 9 of forming a memory device, any of the example methods 1 to 8 of forming a memory device may be implemented at least in part through use of instructions stored as a physical state in one or more machine-readable storage devices.

An example method 10 of forming a memory device can include features of any of the preceding example methods 1 to 9 of forming a memory device and can include performing functions associated with any features of example memory devices 1 to 22 of forming a memory device.

An example machine-readable storage device storing instructions, that when executed by one or more processors, cause a machine to perform operations, can comprise instructions to perform functions associated with any features of example memory devices 1 to 22 or perform methods associated with any features of example methods 1 to 10 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a first set of strings of memory cells positioned on a trench in a substrate, the strings of the first set extending vertically from the trench;
a second set of strings of memory cells positioned on the trench, the strings of the second set extending vertically from the trench, the second set separated from the first set at a mid-trench location of the trench;
a first source plate coupled to the first set of strings, the strings of the first set extending vertically from the first source plate; and
a second source plate coupled to the second set of strings, the strings of the second set extending vertically from the second source plate, the second source plate separated from the first source plate at the mid-trench location separating the first set of strings from the second set of strings, the first and second source plates controllable independent of each other.

2. The memory device of claim 1, wherein the strings of the first set are coupled to a transistor for the strings of the first set and the strings of the second set are coupled to another transistor for the strings of the second set.

3. The memory device of claim 2, wherein the transistor and the other transistor are thin film transistors.

4. The memory device of claim 2, wherein the transistor is associated with a single data line and the other transistor is associated with another single data line.

5. The memory device of claim 1, wherein the strings of the first set of strings are equal in number to the strings of the second set of strings.

6. The memory device of claim 1, wherein the memory device includes additional trenches in a row with the trench, each given trench of the additional trenches having two sets of strings of memory cells positioned thereon, the two sets separated from each other along the given trench at a mid-trench location of the given trench.

7. The memory device of claim 6, wherein:
strings of one set of the two sets of strings of an additional trench, directly adjacent the trench along the row, are coupled to and extend vertically from the second source plate; and
strings of another set of the two sets of strings of the additional trench, directly adjacent the trench along the row, are coupled to and extend from a third source plate, the third source plate controllable independent of the first and second source plates.

8. The memory device of claim 6, wherein the first source plate or the second source plate is coupled to the strings of the two sets of strings of one or more trenches of the additional trenches.

9. A memory device comprising:
rows of trenches in a substrate, each trench having two sets of strings of memory cells positioned thereon, a first set of the two sets separated from a second set of the two sets along the trench at a mid-trench location of the trench, the strings of each of the two sets extending vertically from the trench;
a source segmented into a set of source plates, each source plate controllable independent of other source plates of the set of source plates, with one source segmentation every N mid-trench locations of a row, N being a positive integer, each source plate of the set of source plates coupled to strings of trenches defining segmentation boundaries of the source plate; and
a controller to control the set of source plates to place one or more sets of strings in an off status in a read operation of the memory device.

10. The memory device of claim 9, wherein N equals one.

11. The memory device of claim 9, wherein the source is segmented into sixteen source plates, dividing a page of data into sixteen chunks, each chunk having data locations for one kilobyte.

12. The memory device of claim 9, wherein memory cells that belong to a common chunk of a page are distributed among the rows of trenches having strings of memory cells coupled to one source plate of the set of source plates.

13. The memory device of claim 9, wherein the controller is arranged to read a chunk of a page of data from memory cells of strings distributed among the rows of trenches having strings of memory cells coupled to one source plate of the set of source plates, while holding, in an off-status, one or more chunks of the page distributed among the rows of trenches having strings of memory cells coupled to one or more source plates different from the one source plate.

14. The memory device of claim 9, wherein the rows of trenches are arranged as blocks of memory cells, each block adjacent another block of the blocks of memory cells in a horizontal plane with respect to the strings of each of the two sets of the trenches extending vertically from the trench.

15. A method of forming a memory device, the method comprising:
forming a first set of strings of memory cells positioned on a trench in a substrate, with the strings of the first set extending vertically from the trench;
forming a second set of strings of memory cells positioned on the trench, with the strings of the second set extending vertically from the trench, the second set separated from the first set at a mid-trench location of the trench;
forming a first source plate coupled to the first set of strings such that the strings of the first set extend vertically from the first source plate;
forming a second source plate coupled to the second set of strings such that the strings of the second set extend vertically from the second source plate, the second source plate separated from the first source plate at the mid-trench location of the trench separating the first set of strings from the second set of strings; and
configuring the first and second source plates to be controllable independent of each other.

16. The method of claim 15, wherein forming the first source plate and the second source plate includes:
forming a source region coupled to the strings of the first set of strings and coupled to the strings of the second set of strings; and
cutting the source region at the mid-trench location of the trench separating the first set of strings from the second set of strings.

17. The method of claim 15, wherein the method includes, with the trench being one of multiple trenches arranged as a row of trenches having two sets of strings separated at mid-trench locations, performing one source segmentation every N mid-trench locations, N being a positive integer.

18. The method of claim 17, wherein the method includes forming spaces at the mid-trench locations to perform lateral trim and etch processes, creating breaks in a string pattern in the trenches of the row of trenches.

19. The method of claim 17, wherein the method includes performing the one source segmentation every N mid-trench locations by etching a continuous source region in a backside source process flow.

20. The method of claim 17, wherein the method includes selecting N to fit a performance specification and to meet design constraints for the memory device.
